(19) United States
(12) Patent Application Publication
(10) Pub. No.: US 2015/0325769 A1
(43) Pub. Date: Nov. 12, 2015

(54) THERMOELECTRIC GENERATION MODULE

(71) Applicant: FUJIFILM Corporation, Tokyo (JP)

(72) Inventor: Naoyuki HAYASHI, Ashigarakami-gun (JP)

(73) Assignee: FUJIFILM Corporation, Tokyo (JP)

(21) Appl. No.: 14/802,525

(22) Filed: Jul. 17, 2015

Related U.S. Application Data
(63) Continuation of application No. PCT/JP2014/051414, filed on Jan. 23, 2014.

(30) Foreign Application Priority Data
Jan. 29, 2013 (JP) 2013-014737

(51) Int. Cl. H01L 35/32; H02J 7/34; H02J 7/00

(52) U.S. Cl. CPC H01L 35/32; H02J 7/0045; H02J 7/34

(57) ABSTRACT

A thermoelectric generation module having: a thermoelectric conversion layer in which a plurality of thermoelectric conversion elements are electrically connected to each other in series and radially disposed in a principal surface direction of a substrate; a heat radiation layer that is connected to a center of the thermoelectric conversion layer and disposed on the side opposite to the principal surface of the substrate; a heat insulating layer disposed at a periphery of the heat radiation layer; and a heat absorbing layer that is connected to the periphery of the thermoelectric conversion layer and disposed on the principal surface side of the substrate, wherein the thermoelectric conversion elements each are composed of a p-type semiconductor and an n-type semiconductor, the p-type semiconductor and the n-type semiconductor are alternately and radially disposed, and electrically connected to each other in series with electrodes in sequence.

### CROSS-REFERENCE TO RELATED APPLICATIONS

This application is a Continuation of PCT International Application No. PCT/JP2014/051414 filed on Jan. 23, 2014, which claims priority under 35 U.S.C. §119 (a) to Japanese Patent Application No. 2013-014737 filed in Japan on Jan. 29, 2013. Each of the above applications is hereby expressly incorporated by reference, in its entirety, into the present application.

### TECHNICAL FIELD

The present invention relates to a thermoelectric generation module.

### BACKGROUND ART

A thermoelectric conversion material that allows mutual conversion between heat energy and electric energy is used for a thermoelectric conversion element, such as a thermoelectric generation device and a Peltier device. In thermoelectric generation applying the thermoelectric conversion material, such an advantage is obtained that heat energy can be directly converted into electric power, and that a movable part is not required, and thus the thermoelectric generation is used for a power supply for a wrist watch operated by body temperature, a power supply for remote districts, a space power supply or the like.

In order to stably use the thermoelectric generation as a power supply for a portable device, a chargeable secondary battery is built into the portable device. Further, to charge the secondary battery needs a charger having functions to rectify an electric current fed from an AC power supply to regulate to a predetermined direct voltage. Thus, there is also a limitation on place to consume a power and perform a charging operation.

A secondary battery with a built-in thermoelectric charger has been proposed as an AC power supply-free, chargeable secondary battery. This secondary battery with a built-in thermoelectric charger has: a thermoelectric semiconductor implanted in a ceramic substrate, and has been equipped with a thermoelectric element having an electrode fixed to the thermoelectric semiconductor; a first heat-exchange unit provided on one surface side of the thermoelectric element; a second heat-exchange unit provided on the other surface side of the thermoelectric element; a secondary battery fixed to the second heat-exchange unit; and a means of feeding an output of the thermoelectric element to the secondary battery. Further, the electric energy obtained by power generation using a thermoelectric conversion element is accumulated in the secondary battery (see Patent Literature 1).

The portable device using this secondary battery with a built-in thermoelectric charger makes charge operation unnecessary and, in addition, by reason that no power supply is needed, electricity consumption in case of charge can be cut.

Further, Patent Literature 2 discloses a thermoelectric generator having a substrate and a thermoelectric conversion element formed on one surface of the substrate. The thermoelectric conversion element of this thermoelectric generator is used in such a way that the one surface side of the substrate becomes a low temperature side, and the thermoelectric conversion element uses heat current which flows in the same direction as a thickness direction of the substrate. On the other surface of the substrate, an accumulation (charge) circuit which accumulates electric energy generated by the thermoelectric conversion element has been formed. Further, on the other surface of the substrate, a first wiring which makes an electric connection of the thermoelectric conversion element with the capacitor circuit, is formed, and, above the other surface of the substrate, a radiating fin has been disposed covering the first wiring in planar view.

Further, Non-Patent Literature 1 discloses a constitution, in which a plurality of thermoelectric conversion elements using a heat current in the in-plane direction of the film, are disposed. Further, Patent Literature 3 discloses a thermoelectric conversion module in which a plurality of p-type thermoelectric conversion elements and n-type thermoelectric conversion elements are radially and alternately disposed, and the p-type thermoelectric conversion elements and the n-type thermoelectric conversion elements are alternately and electrically connected to each other in series.

### CITATION LIST

### Patent Literatures

Patent Literature 1: JP-A-11-284235 (“JP-A” means unexamined published Japanese patent application)
Patent Literature 2: JP-A-2012-196081
Patent Literature 3: JP-A-11-233837

### Non-Patent Literature

Non-Patent Literature 1: “A flexible thermoelectric generation element aimed at waste-heat utilization for power generation” by Masatoshi Takeda, CHEMICAL INDUSTRY, February 2012 (edited by Kabushiki Kaisha Kagaku Kogyo-Sha), pp. 58-61.

### SUMMARY OF INVENTION

### Technical Problem

The secondary battery with a built-in thermoelectric charger described in Patent Literature 1 makes it necessary to connect a thermoelectric conversion element and a secondary battery with a wiring of the metal or the like which conducts heat. For this reason, the heat on the high-temperature side of the thermoelectric conversion element conducts to the secondary battery side via the wiring. Further, temperature of the secondary battery increases due to the conductive heat, and thus there is concern that a temperature difference between a low-temperature side and a high-temperature side of the thermoelectric conversion element becomes small, which results in a power generation effect becoming weakened. In Patent Literature 1, no regard is given to such a concern.

Also in Patent Literature 2, no regard is given to such a concern that a temperature difference between a low-temperature side and a high-temperature side of the thermoelectric conversion element becomes small, which results in a power generation effect becoming weakened.

The problem of the present invention is to provide a thermoelectric generation module which is able to achieve a high-generating efficiency, even though the heat source is of low temperature such as a skin surface of the human body or animals and a temperature difference between a low-temperature side and a high-temperature side thereof is small.

### Solution to Problem

According to the present invention, there is provided the following means:

(1) A thermoelectric generation module comprising: a thermoelectric conversion layer in which a plurality of thermoelectric conversion elements are electrically connected to each other in series and radially disposed in a principal surface direction of a substrate; a heat radiation layer that is connected to a center of the thermoelectric conversion layer and disposed on the side opposite to the principal surface of the substrate; a heat insulating layer disposed at a periphery of the heat radiation layer; and a heat absorbing layer that is connected to the periphery of the thermoelectric conversion layer and disposed on the principal surface side of the substrate, wherein the thermoelectric conversion elements each are composed of a p-type semiconductor and an n-type semiconductor, the p-type semiconductor and the n-type semiconductor are alternately and radially disposed, and electrically connected to each other in series with electrodes in sequence, and wherein of the electrodes, a first electrode that is disposed on the center side of the radial shape constitutes a heat conduction pathway for heat radiation to the heat radiation layer via a first heat conducting portion, and a second electrode that is disposed on the periphery side of the radial shape constitutes a heat conduction pathway for heat absorption from the heat absorbing layer to the thermoelectric conversion element via a second heat conducting portion.
(2) The thermoelectric generation module described in the item (1), wherein an adhesive layer is disposed on the surface of the heat absorbing layer.
(3) The thermoelectric generation module described in the item (2), wherein the adhesive layer comprises a silicone resin, an acrylic resin, a urethane resin, a styrene resin, an α-olefin resin, an ethylene/vinyl acetate copolymer resin, an epoxy resin, or a styrene/butadiene rubber resin.
(4) The thermoelectric generation module described in the item (2) or (3), having a non-woven cloth on the surface of the adhesive layer.
(5) The thermoelectric generation module described in any one of the items (1) to (4), wherein the heat insulating layer has a void structure.
(6) The thermoelectric generation module described in any one of the items (1) to (5), mounting a secondary battery that is electrically connected to an output section of the thermoelectric conversion layer.
(7) The thermoelectric generation module described in the item (6), mounting an electronic device that is connected to the secondary battery.

### Advantageous Effects of Invention

The thermoelectric generation module of the present invention is able to obtain a high-generating efficiency even though temperature of heat source is as low as a skin surface of the human body or animals and a temperature difference between a low-temperature side and a high-temperature side of the thermoelectric conversion element is small.

Other and further features and advantages of the invention will appear more fully from the following description, appropriately referring to the accompanying drawings.

### BRIEF DESCRIPTION OF THE DRAWINGS

FIG. 1 is a view showing a thermoelectric generation module for explaining an embodiment of the present invention. FIG. 1(a) is a cross-section view showing schematically a device configuration of the right half of the thermoelectric generation module, and FIG. 1(b) is a plan view showing diagrammatically an example of placement of the thermoelectric conversion elements.

FIG. 2 is a plan view showing a state in which the thermoelectric generation module of the embodiment has been attached to a skin surface.

FIG. 3 is a block diagram showing a preferable example of the configuration for charging the thermoelectric generation module described in the embodiment.

FIG. 4 is a block diagram showing a preferable example of the configuration for discharging the thermoelectric generation module described in the embodiment.

FIG. 5 is a plan view showing diagrammatically a preferable example of the electronic device mounted (implemented) with the thermoelectric generation module mounting a thin-film solid secondary battery.

FIG. 6 is a plan view showing diagrammatically another preferable example of the electronic device mounted with the thermoelectric generation module mounting a thin-film solid secondary battery.

FIG. 7 is a manufacturing process chart showing an example of the manufacturing process of the thermoelectric generation module described in the embodiment, and, as a representative thereof, a device configuration of the right half of the thermoelectric generation module is shown schematically. As a result, the device configuration of the left half of the thermoelectric generation module which is not shown has symmetry of the device configuration of the right half which is shown.

### DESCRIPTION OF EMBODIMENTS

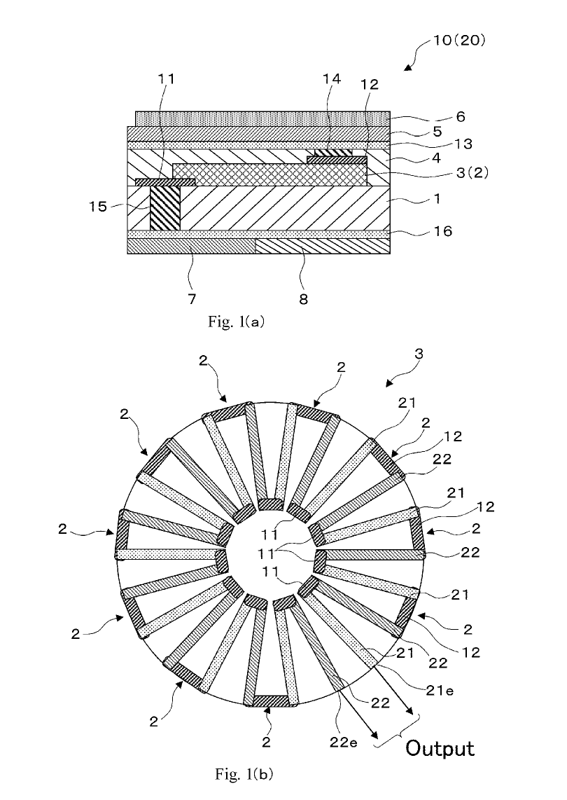

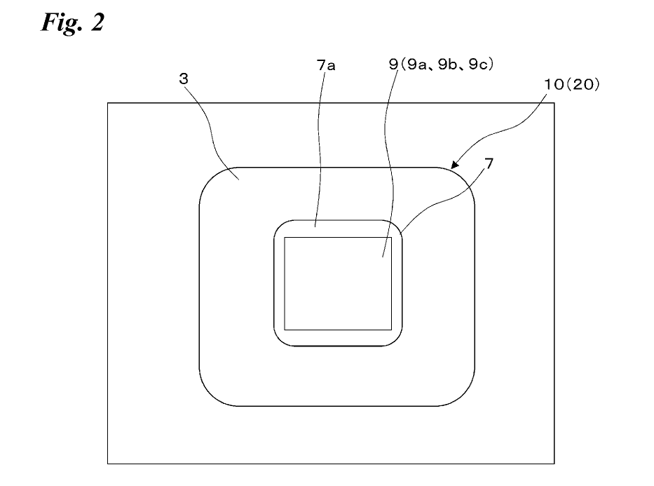

A detailed explanation about a preferable embodiment of the thermoelectric generation module of the present invention is given below on the basis of FIGS. 1 and 2. Note that the present invention is not construed as being limited by the explanation of this embodiment. Further, the device configuration shown in FIG. 1(a) is of the right half of the thermoelectric generation module, and the left half thereof is symmetry of the configuration of the right half.

As shown in FIGS. 1(a) and 1(b), a thermoelectric generation module 10 of the present embodiment is equipped with a thermoelectric generator 20. The thermoelectric generator 20 has a thermoelectric conversion layer 3 in which a plurality of thermoelectric conversion elements 2 are electrically connected to each other in series and radially disposed in the principal surface direction of a substrate 1. On the surface of the substrate 1, an electrode 11 that connects to the thermoelectric conversion element 2 on the center side of the radial shape, is formed. The electrode 11 and the thermoelectric conversion layer 3 are covered with a heat insulating layer 4. On the surface of the heat insulating layer 4, an electrode 12 that connects to the thermoelectric conversion element 2 on the periphery side of the radial shape, is formed. The phrase “a surface of the substrate 1” means the surface side on which the thermoelectric conversion layer 3 is formed. The phrase “a surface of the heat insulating layer 4” means the surface opposite to the side of the substrate 1.

The thermoelectric conversion element 2 is composed of a linear p-type semiconductor 21 and a linear n-type semiconductor 22, in planar view; and the p-type semiconductor 21 and the n-type semiconductor 22 are alternately and radially disposed. Further, the p-type semiconductor 21 and the n-type semiconductor 22 are radially disposed in sequence in any one of a clockwise direction and a counterclockwise direction and connected electrically to each other with electrodes 11 and 12 in series. That is, as a set of the p-type semiconductor 21 and the n-type semiconductor 22, the p-type semiconductor 21 and the n-type semiconductor 22 are electrically connected to each other with the electrode 12 on the periphery side of the radial shape to constitute one thermoelectric conversion element 2. Thus, the electrodes 12 are circularly arranged at an interval. Further, in adjacent thermoelectric conversion elements 2, the p-type semiconductor 21 of one thermoelectric conversion element 2 and the n-type semiconductor 22 of another thermoelectric conversion element 2 adjacent thereto are electrically connected to each other with the electrode 11 on the center side of the radial shape. Thus, the electrodes 11 are circularly arranged at an interval.

As to the p-type semiconductor 21 and the n-type semiconductor 22, from the viewpoint of obtaining an adequate difference in temperature between both ends of each of the semiconductors, for example, the length thereof is at least 10 mm, preferably at least 30 mm, and more preferably at least 100 mm. Further, from the viewpoint of lowering specific resistance, for example, the width thereof is at least 3 mm, preferably at least 5 mm, and more preferably at least 10 mm. Further, from the viewpoint of obtaining larger electric power, the interval between the p-type semiconductor 21 and the n-type semiconductor 22 is equal to or less than 1 mm, preferably equal to or less than 100 μm, and more preferably equal to or less than 50 μm. Further, the thickness of each of the p-type semiconductor and the n-type semiconductor is at least 100 nm, preferably at least 1 μm, and more preferably at least 10 μm.

Further, a heat absorbing layer 5 is disposed above the surface of heat insulating layer 4 via an adhesion layer 13. The heat absorbing layer 5 is connected, via the adhesion layer 13 and first heat conducting portion 14 provided through the heat insulating layer 4, to the electrode 12 disposed on the periphery side of the radial shape. Further, an adhesive layer 6 is disposed on a surface of the heat absorbing layer 5. The phrase “a surface of the heat absorbing layer 5” means the surface opposite to the side of the substrate 1.

A heat radiation layer 7 is disposed via an adhesion layer 16 so that the heat radiation layer 7 is connected to the thermoelectric conversion layer 3 on the center side of the radial shape via a second heat conducting portion 15 through the substrate 1. Further, on the periphery of the heat radiation layer 7, a heat insulating layer 8 is disposed via an adhesion layer 16.

Further as shown in FIG. 2, on a heat radiation surface 7a of the above heat radiation layer 7, a cooling body 9 may be set, in order to enhance radiation performance. As for the cooling body 9, it is possible to use a heat radiation fin 9a formed by a metal which is excellent in heat conductivity, such as aluminum or copper; a refrigerant 9b in which sodium polyacrylate and water or ethylene glycol have been pectized; or a coolant 9c using vaporization heat of water, alcohol or the like. The heat radiation fin 9a or the refrigerant 9b as described above is preferably used, and the refrigerant 9b, formed by pectizing sodium polyacrylate and ethylene glycol, is more preferably used.

Note that the heat absorbing layer 5 may be disposed directly on the heat insulating layer 4, without the adhesion layer 13. Further, the heat radiation layer 7 and the heat insulating layer 8 may be disposed directly on the substrate 1, without the adhesion layer 16.

The above term “radial shape” means a shape in which, with a central focus on one point or region, linear objects are arranged in all directions toward the outside of the one point or region. Note that the shape in which linear objects are arranged toward the outside from the central part in a less than 360-degree range is also included in the radial shape. Further, the above term “linear” means an elongated shape having a certain width.

Further as shown in FIG. 1, wirings (not shown) are connected respectively to a p-type semiconductor 21e and an n-type semiconductor 22e located at both edges of series-connection of the p-type semiconductor 21 and the n-type semiconductor 22. These two wirings are connected, for example, through a pore portion (a contact hole) (not shown) formed by penetrating the substrate 1 from one surface to the backside, from the backside of the substrate 1. Both edges 21e and 22e of the series-connection of the p-type semiconductor 21 and the n-type semiconductor 22 each act as an output terminal of the thermoelectric conversion layer 3 of the thermoelectric generation module 10.

In the thermoelectric conversion element 2, the electrode 12 side is used as a high-temperature side, while the electrode 11 side is used as a low-temperature side, so that electric energy is generated depending on a temperature difference between the electrode 11 and the electrode 12.

As for the substrate 1, it is possible to use any of various substrates, such as a resin substrate, a ceramics substrate, a glass substrate, a metal substrate, a semiconductor substrate, and a composite material substrate. For example, from the viewpoints of high insulation property and light in weight, a glass epoxy substrate is preferably used as a composite material substrate.

As for the thermoelectric conversion material which constitutes the thermoelectric conversion element 2, inorganic materials which are ordinarily used as a thermoelectric conversion material may be used. Examples of preferred thermoelectric conversion materials include Bi (bismuth), Sb (antimony), Te (tellurium), Pb (lead), Se (selenium), Zn (zinc), Co (cobalt), Mn (manganese), Si (silicon), Mg (magnesium), Ge (germanium), and Fe (iron). A mixture composed of at least 2 among these materials is more preferably used, and Bi₂Te₃, Bi₍₂₋ₓ₎SbₓTe₃ (in this case, 0<x<2), CeBi₄Te₆, PbTe, Zn₄Sb₃, CoSb₃, MnSi, Mg₂Si, SiGe, or FeSi₂ is further preferably used.

More specifically, examples of the p-type semiconductor 21 include: Bi₍₂₋ₓ₎SbₓTe₃ (in this case, 0<x<2), PbTe, Zn₄Sb₃, and CeBi₄Te₆; and examples of the n-type semiconductor include: Bi₂Te₃, Bi₂Te_{(3-y)}Se_{y} (in this case, 0<y<3), and Mg₂Si. More preferably, Bi₍₂₋ₓ₎SbₓTe₃ (in this case, 0<x<2) is exemplified as the p-type semiconductor material, and Bi₂Te_{(3-y)}Se_{y} (in this case, 0<y<3) is exemplified as the n-type semiconductor.

The thermoelectric conversion material may contain other ingredients, such as a dopant or the like, in addition to the above-described ones. From the viewpoint of electrical conductivity and the like, the content of the other ingredient in the thermoelectric conversion material is at least 0.1% by mass, preferably at least 0.5% by mass, while preferably equal to or less than 10% by mass, and more preferably equal to or less than 5% by mass. As for specific examples of the dopant, boron and gallium are exemplified as a p-type dopant, and ordinary materials, such as phosphorus, arsenic, antimony, selenium or the like, are exemplified as an n-type dopant.

In addition, for melting point adjustment, a metal, such as aluminum, copper, or silver, may be contained therein in the amount of 0.1% by mass or more and 20% by mass or less.

The heat insulating layer 4 and the heat insulating layer 8 are composed of an insulating material. As an organic insulating material, use may be made of: a polyimide, a polysiloxane, a solder resist, an epoxy resin, a polyparaxylilene, or the like. As an inorganic insulating material, use may be made of: SiO₂, Al₂O₃, Ta₂O₅, ZrO₂, or the like. Preferably, as the organic insulating material, use may be made of: a polyimide, a polysiloxane, a solder resist, or the like; and, as the inorganic insulating material, use may be made of: SiO₂, Al₂O₃, or the like. More preferably, as the organic insulating material, use may be made of a polyimide; and, as the inorganic insulating material, use may be made of SiO₂.

Further, the heat insulating layer 4 and the heat insulating layer 8 are preferably formed so as to incorporate a void structure having voids (air holes) inside. As for the void, from the viewpoint of enhancing the insulation property, the porosity is adjusted to at least 20% by volume, preferably at least 50% by volume, and more preferably at least 80% by volume. Further, from the viewpoint of maintaining a mechanical strength of the heat insulating layer, the porosity is adjusted to 60% by volume or less, preferably 50% by volume or less, and more preferably 45% by volume or less. Further, from the viewpoint of uniformalizing the insulation property in plane, the size of the void (the average void diameter) is adjusted to 20 μm or less, and preferably 10 μm or less. The adhesion is cut, a photograph of the resultant cross-section is taken using an optical microscope or an electronic microscope, and then a minor axis and a major axis of the photographed void are measured. A half of the sum of the thus-measured minor axis and major axis is calculated to obtain the void diameter. Then, an average of the measured void diameter of 50 or 100 voids is defined as an average void diameter.

By incorporating a void structure into the heat insulating layer 4 and the heat insulating layer 8, the electrical insulating property is improved, as well as improvement of heat insulating property, with maintaining the mechanical strength.

In the heat absorbing layer 5, use may be made of: copper, aluminum, silicon, silicon carbide, orientation-processed graphite or carbon fiber, or the like. Preferably, use may be made of: aluminum, silicon, silicon carbide, orientation-processed graphite or carbon fiber, or the like. From the viewpoint of high-heat conductivity, more preferably use may be made of: silicon, orientation-processed graphite or carbon fiber.

In the adhesive layer 6, use may be made of: a polyvinyl alcohol (PVA), a silicone resin, an acrylic resin, a urethane resin, a styrene resin, an α-olefin resin, an ethylene/vinyl acetate copolymer (EVA) resin, an epoxy resin, a styrene/butadiene rubber resin, or the like. Preferably, use may be made of: a silicone resin, an acrylic resin, or the like. More preferably, from the viewpoints of high adhesion property and high biocompatibility, an acrylic resin is used.

Further, from the viewpoint of prevention of skin irritation, a medical gauze or a non-woven cloth may be provided on top. For example, as for the non-woven cloth, use may be preferably made of a non-woven cloth composed of: a polyolefin fiber, a polypropylene fiber, a polyester fiber, and the like. In this case, it is preferable that the thickness of the non-woven cloth is 20 μm or more and 200 μm or less, and the basis weight is 20 g/m² or more and 60 g/m² or less.

As for the measuring method of the above adhesive layer, measurement is carried out using JIS standard: JISZ0237 “Adhesive tape•Adhesive sheet Testing method.”

In the heat radiation layer 7, use may be made of: copper, aluminum, silicon, silicon carbide, orientation-processed graphite or carbon fiber, or the like. Preferably, use may be made of: aluminum, silicon, silicon carbide, orientation-processed graphite or carbon fiber, or the like. More preferably, from the viewpoint of high-heat conductivity, use may be made of: silicon, orientation-processed graphite or carbon fiber.

In the electrodes 11 and 12, from the viewpoints of having electric conductivity and heat conductivity, known metals are used, such as copper, silver, gold, platinum, nickel, chromium, a copper alloy, or the like. Preferably, use may be made of: copper, gold, platinum, nickel, a copper alloy, or the like. More preferably, gold, platinum, or nickel is used.

In the adhesion layer 13, use may be made of a hot melt adhesive and the like, composed of, such as a silicone resin, an acrylic resin, a urethane resin, a styrene resin, an α-olefin resin, an ethylene/vinyl acetate copolymer (EVA) resin, an epoxy resin, a styrene/butadiene rubber resin, a polyolefin resin, a polyester resin, or the like. Preferably, use may be made of a hot melt adhesive and the like, such as a silicone resin, an acrylic resin, a urethane resin, a polyolefin resin, a polyester resin, or the like. More preferably, from the viewpoints of high-adhesion property and high flexibility, use may be made of a hot melt adhesive, such as an acrylic resin, a urethane resin, a polyolefin resin, a polyester resin, or the like.

In the adhesion layer 16, use may be made of a hot melt adhesive and the like, composed of, such as a silicone resin, an acrylic resin, a urethane resin, a styrene resin, an α-olefin resin, an ethylene/vinyl acetate copolymer (EVA) resin, an epoxy resin, a styrene/butadiene rubber resin, a polyolefin resin, a polyester resin, or the like. Preferably, use may be made of a hot melt adhesive and the like, such as a silicone resin, an acrylic resin, a urethane resin, a polyolefin resin, a polyester resin, or the like. More preferably, from the viewpoints of high-adhesion property and high flexibility, use may be made of a hot melt adhesive, such as an acrylic resin, a urethane resin, a polyolefin resin, a polyester resin, or the like.

In the first heat conducting portion 14, use may be made of a rubber, a grease, a gel, or the like, each of which has dispersed therein a material high in heat conductivity, including: an inorganic filler, such as aluminum nitride, silicon nitride, or silicon carbide; a carbon; a carbon nanotube; and the like. Preferably, use may be made of a grease, a gel, or the like, each of which has dispersed therein the material high in heat conductivity, including: the inorganic filler, such as aluminum nitride, silicon nitride, or silicon carbide; a carbon; a carbon nanotube; and the like. More preferably, from the viewpoint of high heat conductivity, use may be made of a pectized inorganic filler, such as aluminum nitride, silicon nitride, or silicon carbide.

In the second heat conducting portion 15, use may be made of a rubber, a grease, a gel, or the like, each of which has dispersed therein a material high in heat conductivity, including: an inorganic filler, such as aluminum nitride, silicon nitride, or silicon carbide; a carbon; a carbon nanotube; and the like. Preferably, use may be made of a grease, a gel, or the like, each of which has dispersed therein the material high in heat conductivity, including: the inorganic filler, such as aluminum nitride, silicon nitride, or silicon carbide; a carbon; a carbon nanotube; and the like. More preferably, from the viewpoint of high heat conductivity, use may be made of a pectized inorganic filler, such as aluminum nitride, silicon nitride, or silicon carbide.

In the thermoelectric generation module 10, inside the p-type semiconductor 21, a potential difference is caused by a positive charge (a positive hole) that transfers from the side of the electrode 22 high in temperature to the side of the electrode 21 low in temperature, whereby a thermal electromotive force is generated. Further, inside the n-type semiconductor 22, energy of conduction electrons on the side of the electrode 22 high in temperature gets higher. As a result, a potential difference is caused by transferring the conduction electrons in the direction of the electrode 21 low in temperature, whereby a thermal electromotive force is generated. Further, a potential difference between the p-type semiconductor 21 and the n-type semiconductor 22 become opposite. As a result, an electric current flows only one way due to a serial connection of the p-type semiconductor 21 and the n-type semiconductor 22. An electric power can be obtained by output of the electric current to the outside. This electromotive phenomenon is called as Seebeck effect.

Specifically, the thermoelectric generation module 10 is adhered to, for example, a skin surface of the human body, by the adhesive layer 6 disposed on the surface of the heat absorbing layer 5. In this case, the heat of the human body as a heat source conducts from its skin surface to the heat absorbing layer 5 through the adhesive layer 6. At this time, the heat absorbed by the heat absorbing layer 5 is prohibited from further transfer to the next thermoelectric conversion layer 3, because the heat insulating layer 4 is disposed on the side opposite to the adhesive layer 6 of the heat absorbing layer 5. As a result, the heat absorbed by the heat absorbing layer 5 is transmitted to the first heat conducting portion 14 and transferred in a focused manner to the end of the thermoelectric conversion element 2 on the periphery side of the radial shape. Thus, at the high-temperature side of the thermoelectric conversion element 2, high temperature is maintained effectively.

On the other hand, in the central side of the radial shape, which is the low-temperature side (opposite side to the high-temperature side) of the thermoelectric conversion element 2, because the heat radiation layer 7 is connected to the thermoelectric conversion element 2 via the second heat conducting portion 15, the heat transferred from the high-temperature side in the thermoelectric conversion element 2 is exhausted effectively to the heat radiation layer 7 via the second heat conducting portion 15 at the low-temperature side. Further, because the heat radiation layer 7 is disposed via the substrate 1 with respect to the thermoelectric conversion element 2, and because the heat insulating layer 8 is disposed on the periphery side of the heat radiation layer 7, the heat radiation layer 7 is shut away from impact of heat emitted from the heat source. As a result, this heat radiation layer allows the heat transferred efficiently in the thermoelectric conversion element 2 to exhaust to the outside. Thus, in the low-temperature side of the thermoelectric conversion element 2, a low-temperature is maintained efficiently.

In this way, the high-temperature side and the low-temperature side occur in the thermoelectric conversion element 2, so that thermoelectric generation can be achieved efficiently, even if the temperature of the heat source is as low as a body temperature of a human or an animal.

Further, in the thermoelectric generation module 10, the thermoelectric conversion element 2 is disposed radially, so that the length in the heat flow direction can be elongated, so as to obtain an adequate distance between the starting point side of the radial shape and its periphery side, while placing the thermoelectric conversion element 2 in a narrow layout area. As a result, a big difference in temperature can be obtained. This also allows power generation to be achieved efficiently, in spite of a low-temperature heat source.

Further, the heat absorbing layer 5 is connected to the one end (high temperature side) of the thermoelectric conversion element 2 in the thermoelectric conversion layer 3 via the heat conducting portion 14, whereby heat absorption is advanced in a focused manner from the one end (high temperature side) of the thermoelectric conversion element 2. Further, the heat radiation layer 7 is connected to the other end (low temperature side) of the thermoelectric conversion element 2 in the thermoelectric conversion layer 3 via the heat conducting portion 15, whereby heat radiation is advanced in a focused manner from the other end (low temperature side) of the thermoelectric conversion element 2. As a result, in the thermoelectric conversion element 2, a temperature difference between both ends thereof becomes larger. Thus, the generating efficiency due to the thermoelectric conversion layer 3 can be enhanced.

Further, the adhesive layer 6 provided on a surface of the heat absorbing layer 5 enables the thermoelectric generation module 10 to adhere to a heat source. For example, this makes it possible to make the adhesive layer 6 of the thermoelectric generation module 10 adhere tightly to a skin or the like, whereby a gap (an interspace) between the heat source and the adhesive layer 6 becomes difficult to occur. Consequently, in spite of a low-temperature heat source, the heat absorbing layer 5 is able to absorb efficiently the heat given off from the heat source.

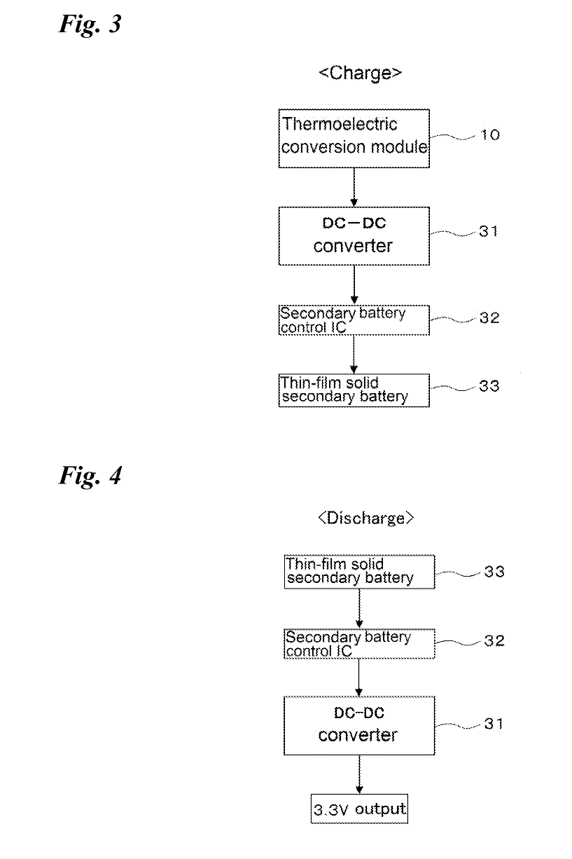

Next, explanation is given about a preferable configuration example in charge and discharge of the thermoelectric generation module 10 mounting a thin-film solid secondary battery which has been electrically connected to the output section of the thermoelectric conversion layer 3, with reference to FIG. 3 and FIG. 4.

As shown in FIG. 3, a preferable example of the configuration of charge is explained below.

The power generated by the thermoelectric generation module 10 is a direct-current power, and because of the low voltage, the power, as it is, is difficult to be used for a power required to drive an electronic devise and the like. The voltage obtained by the thermoelectric generation module 10 is therefore increased by means of a DC-DC converter 31. For example, the voltage is increased to 4.0V.

Then, the power with the increased voltage is charged to the thin-film solid secondary battery as a secondary battery 33 via a secondary battery control IC 32, which controls charge and discharge of the secondary battery 33. The secondary battery control IC 32 is composed of a charging power supply device, which produces a direct-current power, and a charge control circuit, which controls charging of the buttery, although these devices are not shown.

As shown in FIG. 4, a preferable example of the configuration of discharge is explained below.

The power discharged from the thin-film solid secondary battery as the secondary battery 33 via the secondary battery control IC 32 is transferred to the DC-DC converter 31. By the DC-DC converter 31, the voltage is converted to a voltage to be used for electronic devices (not shown) and then the thus-converted power is output. Ordinarily, the working voltage for the electronic devices is set to any of various voltages. The voltage is therefore dropped or increased to a working voltage suitable for the electronic devices by the DC-DC converter 31. For example, the voltage is transformed to 3.3V and then the thus-transformed power is output.

As for the above DC-DC converter 31, use may be made, for example, of ETC310 manufactured by En Ocean, LTC3108 and LTC3109 each manufactured by Linear Technology, or the like.

As for the above secondary battery control IC 32, use may be made, for example, of LTC4070 and LTC4071 each manufactured by Linear Technology, MAX17710 manufactured by Maxim Integrated Product, or the like.

As for the above thin-film solid secondary battery, use may be made, for example, of MEC201 and MEC220 each manufactured by Infinite Power Solution, or the like.

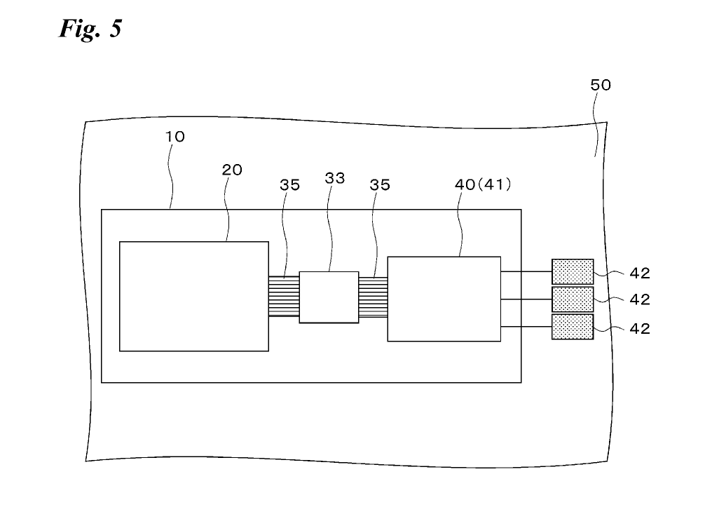

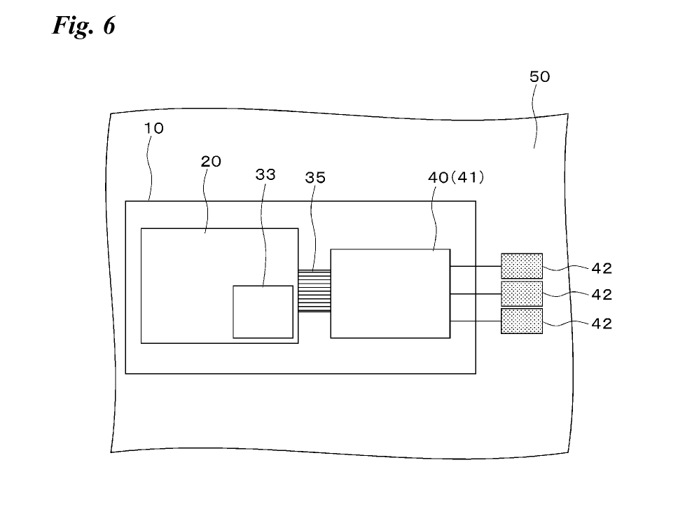

Next, explanation is given about a thermoelectric generation module mounting a thin-film solid secondary battery as a secondary battery, which is electrically connected to an output section of a thermoelectric conversion layer, with reference to FIG. 5 and FIG. 6.

As shown in FIG. 5, a thermoelectric generation module 10 is attached to a skin 50 via an adhesive layer 6 (see FIG. 1). The adhesive layer 6 is therefore preferably formed all over the surface side of the thermoelectric generation module 10.

A thermoelectric generator 20, a secondary battery 33 (for example, a thin-film solid secondary batter), and an electrocardiogram monitor device (41) as an electronic device 40, all of which constitute the thermoelectric generation module 10, are connected with a cable 35 mounting a secondary battery control IC 32 (see FIGS. 3 and 4) or the like on a flexible substrate (not shown). As for the cable 35, use may be made of a FPC (flexible print circuit) cable or FFC (flexible flat cable). Further, an electrode 42, which is connected to the electrocardiogram monitor device 41, is adhered to the skin 50.

Further as shown in FIG. 6, the secondary battery 33 may be mounted in the thermoelectric generator 20. Even in this configuration, the thermoelectric generation module 10 is also attached to the skin 50 via the adhesive layer 6 (see FIG. 1). The adhesive layer 6 is therefore preferably formed all over the surface side of the thermoelectric generation module 10. Further, the thermoelectric generator 20 and the electrocardiogram monitor device 41, each of which constitute the thermoelectric generation module 10, are connected with the cable 35 mounting the secondary battery control IC 32 (see FIGS. 3 and 4) or the like on the flexible substrate (not shown). As for the cable 35, use may be made of a FPC (flexible print circuit) cable or FFC (flexible flat cable). Further, the electrode 42, which is connected to the electrocardiogram monitor device 41 as the electronic device 40, is adhered to the skin 50.

In the above, explanation is given about an example of the electrocardiogram monitor device 41, which is mounted as the electronic device 40 to be mounted in the thermoelectric generation module 10. As to the electronic device 40, other than the electrocardiogram monitor device, it is possible to mount any of various wearable electronic devices to be attached to a skin, such as a pulse monitor, a manometer, a wristwatch, a pedometer, a radio transmitting a locational information, a thermometer, or a vibration meter. In the case of mounting any of these electronic devices, it is only necessary to substitute the electrocardiogram monitor device 41 with any of these electronic devices, in the above configuration shown in FIGS. 5 and 6.

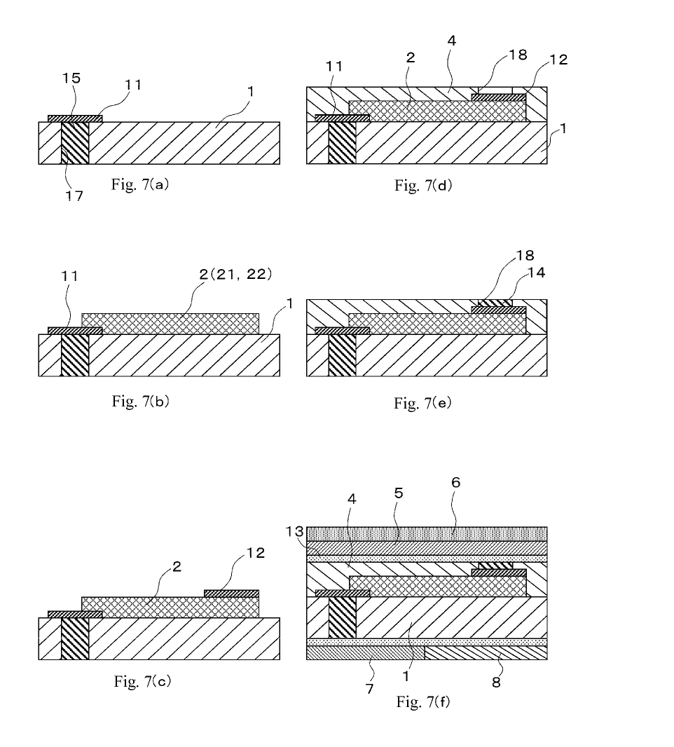

Next, explanation is given below about an example of the preferable method of producing the thermoelectric generation module 10, with reference to FIG. 7. Note that the device configuration shown in FIG. 7 is a right half of the thermoelectric generation module, and the left half thereof is symmetrical to the right half of the configuration.

As shown in FIG. 7(a), a second heat conducting portion 15 as a through-hole for heat conduction is formed in a substrate 1. As for the substrate 1, for example, a glass epoxy substrate is used. Firstly, a through-hole 17 is formed in the substrate 1. The through-hole 17 is formed, so as to connect, in the later process, to the region where an electrode with which a p-type semiconductor and an n-type semiconductor of the radially-formed thermoelectric conversion element are connected. The through-hole 17 is therefore placed circularly in a predetermined interval.

Formation of the through-hole 17 is preferably carried out by drilling, a laser ablation, or the like. Note that a desmear treatment may be carried out as needed.

Next, a material good in heat conductivity is buried within the through-hole 17, to form the second heat conducting portion 15. The method of burying the material good in heat conductivity is preferably carried out by plating, an electrically-conductive paste, or the like.

Next, an electrode 11, which connects to the above second heat conducting portion 15, is formed on a surface of the substrate 1. In the electrode 11, any of known metals is used, such as copper, silver, gold, platinum, nickel, chromium, a copper alloy, or the like. The method of forming the electrode 11 is preferably carried out by plating, patterning by etching, sputtering or ion plating using liftoff, or sputtering or ion plating using a metal mask.

Alternatively, a metal paste may be used, in which the above metal is subjected to microparticulation, and a binder and a solvent are added thereto. In the case of using the metal paste, screen printing, or printing by dispenser may be used. After the printing, application of heat for drying, or a heating treatment for decomposition of the binder or sintering the metal may be carried out.

As shown in FIG. 7(b), a thermoelectric conversion element 2 connecting to the electrode 11 is formed on a surface of the substrate 1. The thermoelectric conversion element 2 is formed by arranging a p-type semiconductor 21 and an n-type semiconductor 22, as shown in FIG. 1(b). It makes no difference which is formed first, the p-type semiconductor 21 or the n-type semiconductor 22. For example, after forming the p-type semiconductor 21, the n-type semiconductor 22 is formed.

As described above, examples of the p-type semiconductor 21 include: Bi₍₂₋ₓ₎SbₓTe₃ (in this case, 0<x<2), PbTe, Zn₄Sb₃, and CeBi₄Te₆; and examples of the n-type semiconductor include: Bi₂Te₃, Bi₂Te_{(3-y)}Se_{y} (in this case, 0<y<3), and Mg₂Si. More preferably, Bi₍₂₋ₓ₎SbₓTe₃ is exemplified as the p-type semiconductor material, and Bi₂Te_{(3-y)}Se_{y} is exemplified as the n-type semiconductor.

The formation method thereof is preferably carried out by sputtering or ion plating using liftoff, or sputtering or ion plating using a metal mask.

The sputtering is exemplified as the method of forming a semiconductor, but the method of forming a semiconductor is not limited in particular. With the exception of the sputtering, vapor deposition may be adopted, as long as this method is capable of forming a film of the p-type semiconductor 21 and the n-type semiconductor 22 by depositing a thermoelectric conversion material on the substrate 1. For example, use can be preferably adopted: physical vapor deposition, such as pulse laser deposition, vacuum deposition, electron-beam deposition, ion plating, plasma-assist deposition, ion-assist deposition, reactive deposition, laser ablation, or aerosol deposition; or chemical vapor deposition, such as thermal CVD, catalytic chemical vapor deposition, plasma CVD, or metal-organic chemical vapor deposition. Among these methods, sputtering, ion plating, and plasma CVD are preferable.

In the vapor deposition, a powder or target of the above-mentioned thermoelectric conversion material is used. In the case of using two or more kinds of the materials mentioned above as a thermoelectric conversion material, from the viewpoint of easiness in handling or the like, a mixture in which each of ingredients has been mixed in advance, is preferably used.

The film formation of each semiconductor layer by the vapor deposition may be carried out at room temperature, or by heating a substrate approximately to a temperature of 150 to 350° C. If the film formation is carried out by heating the substrate, crystallization of the ingredient progresses, so that a good thermoelectric conversion performance is preferably obtained.

After the film formation of the semiconductor, the thermoelectric conversion element 2 is subjected to annealing. By the annealing, crystallization of the thermoelectric conversion element progresses, so that a thermoelectric conversion performance is improved. Crystallization progresses to some extent by heating the substrate at the time of the above vapor deposition. By carrying out the annealing after the film formation, however, adequate crystallization is achieved, so that the thermoelectric conversion performance can be further improved.

The annealing of the thermoelectric conversion element 2 is a useful treatment, because this enhances crystallinity of the thermoelectric conversion element 2, thereby for improving the thermoelectric conversion performance.

The temperature of the annealing is preferably set to the range of 350° C. or more and 500° C. or less. By carrying out the annealing within the above temperature range, the thermoelectric conversion element 2 can be obtained, which is high in crystallinity and which exerts a good thermoelectric conversion performance.

As to the atmosphere at the annealing, an inert gas atmosphere is preferable. As for the inert gas, use may be made of: argon, helium, or a nitrogen gas. In the case where reduction of the thermoelectric conversion element 2 is desired, use may be made of: argon/hydrogen, nitrogen/hydrogen gas, or the like. The pressure at this time is not limitative in particular, but it may be any of reduced pressure, atmospheric pressure, and application of pressure.

As to the annealing time period, although it varies depending on the size, thickness, or the like of the thermoelectric conversion element 2, it is only necessary to carry out the annealing until crystallization of the thermoelectric conversion element 2 progresses adequately. The treatment time period is ordinarily set to the range of 10 minutes or more and 12 hours or less, and preferably 1 hour or more and 4 hours or less.

The film thickness of the thermoelectric conversion element 2 after the film formation and the annealing is not determined unilaterally, because it varies also depending on the film formation method of the thermoelectric conversion element 2. However, it is preferred for the thermoelectric conversion element 2 to have a certain level of thickness, because if the film thickness is too thin, application of the temperature difference becomes difficult. In the case of film formation by the vapor deposition, the film thickness of the thermoelectric conversion element 2 is at least 100 nm, preferably at least 1 μm, and more preferably at least 10 μm.

Next, as shown in FIG. 7(c), an electrode 12 is formed on the thermoelectric conversion element 2 at the radial periphery portion. In the electrode 12, use may be made of: any of known metals, such as copper, silver, gold, platinum, nickel, chromium, a copper alloy, or the like. The method of forming the electrode 12 is preferably carried out by: plating, patterning by etching, sputtering or ion plating using liftoff, or sputtering or ion plating using a metal mask.

Next, as shown in FIG. 7(d), a heat insulating layer 4, which covers the thermoelectric conversion element 2, the electrode 11, the electrode 12, and the like, and which has an opening 18 provided on the electrode 12, is formed on a surface of the substrate 1. In this heat insulating layer 4, a resin film is used. As for the resin film, for example, a film formed by using a soluble polyimide, is used. As to the formation method of the resin film, a coating method may be used. For example, as for the printing method, use may be made of: die coating, blade coating, bar coating, screen printing, stencil printing, roll coating, curtain coating, spray coating, dip coating, inkjetting, or the like. Preferably, screen printing is used.

After coating, drying is carried out if needed. For example, by blowing a heated air, a solvent can be evaporated, to be dried.

Next, as shown in FIG. 7(e), a first heat conducting portion 14 is formed at the above opening 18. As for the first heat conducting portion 14, a material high in heat conductivity is used. For example, use may be made of: a rubber, a grease, or a gel, each of which has dispersed therein a material high in heat conductivity, including: an inorganic filler, such as aluminum nitride, silicon nitride, or silicon carbide; a carbon; a carbon nanotube; and the like. This production method is preferably carried out according: a method of forming it by coating and drying the above rubber, grease, gel, or its precursor in which the material high in heat conductivity has been dispersed; a method of pressure-bonding it after molding; or the like.

Next, as shown in FIG. 7(f), a heat absorbing layer 5 is adhered on a surface of the heat insulating layer 4 via an adhesion layer 13. As for the adhesion layer 13 and the heat absorbing layer 5, the above-mentioned materials may be used.

Further, an adhesive layer 6 is adhered on a surface of the heat absorbing layer 5. As for the adhesive layer 6, the above-mentioned material is preferably used.

The formation of the adhesion layer 13 is preferably carried out by: screen printing, blade coating, die coating, or dispenser. Further, the heat absorbing layer 5 is adhered to the adhesion layer 13 by pressure bonding. Further, the adhesive layer 6 is adhered to the heat absorbing layer 5 by pressure bonding.

Further, an adhesion layer 16 is formed on the back side of the substrate 1. As a method of forming the adhesion layer 16, the same method as the above-mentioned adhesion layer 13 may be adopted. Further, a heat radiation layer 7 is adhered to the adhesion layer 16 by pressure bonding, and a heat insulating layer 8 is adhered thereto by pressure bonding. As for the heat radiation layer 7 and the heat insulating layer 8, the above-mentioned materials are preferably used.

The above-mentioned thermoelectric generation module 10 can be preferably used for intended purposes, such as a wristwatch power supply, a compact medical device power supply, a compact life-supporting device-driving power supply, a semiconductor device-driving power supply, a compact sensor power supply, and the like.

Having described our invention as related to the present embodiments, it is our intention that the invention not be limited by any of the details of the description, unless otherwise specified, but rather be construed broadly within its spirit and scope as set out in the accompanying claims.

### REFERENCE SIGNS LIST

1 Substrate
2 Thermoelectric conversion element
3 Thermoelectric conversion layer
4 Heat insulating layer
5 Heat absorbing layer
6 Adhesive layer
7 Heat radiation layer
8 Heat insulating layer
9 Cooling body
10 Thermoelectric generation module
11 Electrode (first electrode)
12 Electrode (second electrode)
13, 16 Adhesion layer
14 First heat conducting portion
15 Second heat conducting portion
17 Through-hole
18 Opening
20 Thermoelectric generator
31 DC-DC converter
32 Secondary battery control IC
33 Secondary battery
35 Cable
40 Electrocardiogram monitor device
41 Electrode
50 Skin

1. A thermoelectric generation module comprising:
a thermoelectric conversion layer in which a plurality of thermoelectric conversion elements are electrically connected to each other in series and radially disposed in a principal surface direction of a substrate;
a heat radiation layer that is connected to a center of the thermoelectric conversion layer and disposed on the side opposite to the principal surface of the substrate;
a heat insulating layer disposed at a periphery of the heat radiation layer; and
a heat absorbing layer that is connected to the periphery of the thermoelectric conversion layer and disposed on the principal surface side of the substrate,
wherein the thermoelectric conversion elements each are composed of a p-type semiconductor and an n-type semiconductor, the p-type semiconductor and the n-type semiconductor are alternately and radially disposed, and electrically connected to each other in series with electrodes in sequence, and
wherein of the electrodes, a first electrode that is disposed on the center side of the radial shape constitutes a heat conduction pathway for heat radiation to the heat radiation layer via a first heat conducting portion, and a second electrode that is disposed on the periphery side of the radial shape constitutes a heat conduction pathway for heat absorption from the heat absorbing layer to the thermoelectric conversion element via a second heat conducting portion.

2. The thermoelectric generation module according to claim 1, wherein an adhesive layer is disposed on the surface of the heat absorbing layer.

3. The thermoelectric generation module according to claim 2, wherein the adhesive layer comprises a silicone resin, an acrylic resin, a urethane resin, a styrene resin, an α-olefin resin, an ethylene/vinyl acetate copolymer resin, an epoxy resin, or a styrene/butadiene rubber resin.

4. The thermoelectric generation module according to claim 2, having a non-woven cloth on the surface of the adhesive layer.

5. The thermoelectric generation module according to claim 1, wherein the heat insulating layer has a void structure.

6. The thermoelectric generation module according to claim 1, mounting a secondary battery that is electrically connected to an output section of the thermoelectric conversion layer.

7. The thermoelectric generation module according to claim 6, mounting an electronic device that is connected to the secondary battery.
